(19) United States
(12) Patent Application Publication
(10) Pub. No.: US 2024/0407170 A1
(43) Pub. Date: Dec. 5, 2024

(54) STRUCTURE AND FABRICATION METHOD OF PERIPHERAL TRANSISTOR WITH EPI-SI CONTACTS IN MEMORY DEVICES

(71) Applicant: Applied Materials, Inc., Santa Clara, CA (US)

(72) Inventors: Chang Seok Kang, Santa Clara, CA (US); Raman Gaire, Mechanicville, NY (US); Hsueh Chung Chen, Cohoes, NY (US); In Soo Jung, Campbell, CA (US); Houssam Lazkani, Schenectady, NY (US); Hui Zhao, Saratoga, CA (US); Liu Jiang, Dublin, CA (US); Balasubramanian Pranatharthiharan, San Jose, CA (US); El Mehdi Bazizi, San Jose, CA (US)

(73) Assignee: Applied Materials, Inc., Santa Clara, CA (US)

(21) Appl. No.: 18/659,256

(22) Filed: May 9, 2024

Related U.S. Application Data
(60) Provisional application No. 63/469,609, filed on May 30, 2023.

(51) Int. Cl. H10B 43/40; H10B 41/35; H10B 41/49; H10B 43/23; H10B 43/35

(52) U.S. Cl. CPC H10B 43/40; H10B 41/35; H10B 41/49; H10B 43/23; H10B 43/35

(57) ABSTRACT

Methods and structures to achieve low voltage (LV) and high voltage (HV) scale-down by suppressing the short channel effect of LV as well as increasing breakdown voltage of HV transistor are provided. A semiconductor device comprises a first transistor comprising a first well region of a first conductivity type, a first gate region disposed above the first well region, and a first contact region including a first epitaxial semiconductor adjacent to the first gate region; and a second transistor comprising a second well region of a second conductivity, a second gate region disposed above the second well region, and a second contact region including a second epitaxial semiconductor adjacent to the second gate region.

### CROSS-REFERENCE TO RELATED APPLICATIONS

This application claims priority to U.S. Provisional Application No. 63/469,609, filed May 30, 2023, the entire disclosure of which is hereby incorporated by reference herein.

### TECHNICAL FIELD

Embodiments of the disclosure generally relate to semiconductor devices. More particularly, embodiments of the disclosure are directed to peripheral circuits including high voltage and low voltage metal-oxide-semiconductor field-effect transistors (MOSFETs) and methods of fabrication.

### BACKGROUND

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals.

The MOSFET is by far the most common transistor in digital circuits, as hundreds of thousands or millions of MOSFETs may be included in a memory chip or microprocessor. Since MOSFETs can be made with either p-type or n-type semiconductors, complementary pairs of MOS transistors can be used to make switching circuits with very low power consumption, in the form of complementary metal-oxide-semiconductor (CMOS) logic.

A NAND flash memory chip may be composed of a cell array and peripheral circuits including X-decoder, Y-decoder, and other circuits. To reduce the size of the cell array for a given memory density, the cell array may have a 3-dimensional structure (e.g., 3D NAND). For each generation of 3D NAND flash memory, the number of memory stacks has been increased. The scaling-down of peripheral circuits, however, has been much slower than the increase of memory density. The peripheral circuits of NAND devices are by the low voltage transistor and the high voltage transistor. The low voltage transistor constitutes a large portion of page buffer (PB), and the high voltage transistor occupies most area of the word line (WL) decoder (i.e., X-decoder). The most critical challenge in high voltage and low voltage transistor scale down is to obtain high breakdown voltage (˜30V) and to suppress short channel effects, respectively. Accordingly, there is a need for improved devices and methods of manufacture.

### SUMMARY

One or more embodiments of the disclosure are directed to a semiconductor device. In one or more embodiments, a semiconductor device comprises: a first transistor comprising a first well region of a first conductivity type, a first gate region disposed above the first well region, and a first contact region including a first epitaxial semiconductor adjacent to the first gate region; and a second transistor comprising a second well region of a second conductivity, a second gate region disposed above the second well region, and a second contact region including a second epitaxial semiconductor adjacent to the second gate region.

Additional embodiments of the disclosure are directed to methods of manufacturing a semiconductor device. In one or more embodiments, a method of manufacturing a semiconductor device comprises: patterning a first contact region on a first transistor and a second contact region on a second transistor; growing an epitaxial semiconductor on the first transistor and the second transistor; and trimming a portion of the epitaxial semiconductor on the first transistor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a process flow diagram of a method according to one or more embodiments;

FIG. 2A illustrates a cross-section view of a semiconductor device according to one or more embodiments;

FIG. 2B illustrates a cross-section view of a semiconductor device according to one or more embodiments;

FIG. 2C illustrates a cross-section view of a semiconductor device according to one or more embodiments;

FIG. 2D illustrates a cross-section view of a semiconductor device according to one or more embodiments;

FIG. 2E illustrates a cross-section view of a semiconductor device according to one or more embodiments;

FIG. 2F illustrates a cross-section view of a semiconductor device according to one or more embodiments;

FIG. 2G illustrates a cross-section view of a semiconductor device according to one or more embodiments;

FIG. 2H illustrates a cross-section view of a semiconductor device according to one or more embodiments;

FIG. 2I illustrates a cross-section view of a semiconductor device according to one or more embodiments;

FIG. 2J illustrates a cross-section view of a semiconductor device according to one or more embodiments;

FIG. 2K illustrates a cross-section view of a semiconductor device according to one or more embodiments;

FIG. 2L illustrates a cross-section view of a semiconductor device according to one or more embodiments;

FIG. 2M illustrates a cross-section view of a semiconductor device according to one or more embodiments;

FIG. 2N illustrates a cross-section view of a semiconductor device according to one or more embodiments;

FIG. 2O illustrates a cross-section view of a semiconductor device according to one or more embodiments;

FIG. 3A illustrates a cross-section view of a semiconductor device according to one or more embodiments;

FIG. 3B illustrates a cross-section view of a semiconductor device according to one or more embodiments;

FIG. 3C illustrates a cross-section view of a semiconductor device according to one or more embodiments;

FIG. 3D illustrates a cross-section view of a semiconductor device according to one or more embodiments;

FIG. 3E illustrates a cross-section view of a semiconductor device according to one or more embodiments;

FIG. 3F illustrates a cross-section view of a semiconductor device according to one or more embodiments;

FIG. 3G illustrates a cross-section view of a semiconductor device according to one or more embodiments;

FIG. 3H illustrates a cross-section view of a semiconductor device according to one or more embodiments;

FIG. 3I illustrates a cross-section view of a semiconductor device according to one or more embodiments;

FIG. 3J illustrates a cross-section view of a semiconductor device according to one or more embodiments;

FIG. 3K illustrates a cross-section view of a semiconductor device according to one or more embodiments;

FIG. 3L illustrates a cross-section view of a semiconductor device according to one or more embodiments;

FIG. 3M illustrates a cross-section view of a semiconductor device according to one or more embodiments;

FIG. 3N illustrates a cross-section view of a semiconductor device according to one or more embodiments;

FIG. 3O illustrates a cross-section view of a semiconductor device according to one or more embodiments;

FIG. 3P illustrates a cross-section view of a semiconductor device according to one or more embodiments;

FIG. 4A illustrates a cross-section view of a semiconductor device according to one or more embodiments;

FIG. 4B illustrates a cross-section view of a semiconductor device according to one or more embodiments;

FIG. 4C illustrates a cross-section view of a semiconductor device according to one or more embodiments;

FIG. 4D illustrates a cross-section view of a semiconductor device according to one or more embodiments;

FIG. 4E illustrates a cross-section view of a semiconductor device according to one or more embodiments;

FIG. 4F illustrates a cross-section view of a semiconductor device according to one or more embodiments;

FIG. 4G illustrates a cross-section view of a semiconductor device according to one or more embodiments;

FIG. 4H illustrates a cross-section view of a semiconductor device according to one or more embodiments; and

FIG. 5 illustrates a cluster tool according to one or more embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface. What a given substrate surface comprises will depend on what films are to be deposited, as well as the particular chemistry used.

As used in this specification and the appended claims, the terms “precursor,” “reactant,” “reactive gas” and the like are used interchangeably to refer to any gaseous species that can react with the substrate surface.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate and exhibit a doping profile suitable for a particular application. The gate is positioned over the channel region and includes a gate dielectric interposed between a gate electrode and the channel region in the substrate.

As used herein, the term “field effect transistor” or “FET” refers to a transistor that uses an electric field to control the electrical behavior of the device. Enhancement mode field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated Is and current entering the channel at the drain (D) is designated I_{D}. Drain-to-source voltage is designated V_{DS}. By applying voltage to gate (G), the current entering the channel at the drain (i.e., I_{D}) can be controlled.

The metal-oxide-semiconductor field-effect transistor (MOSFET) is a type of field-effect transistor (FET). It has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

If the MOSFET is an n-channel or nMOS FET, then the source and drain are n+ regions and the body is a p region. If the MOSFET is a p-channel or pMOS FET, then the source and drain are p+ regions and the body is an n region. The source is so named because it is the source of the charge carriers (electrons for n-channel, holes for p-channel) that flow through the channel; similarly, the drain is where the charge carriers leave the channel.

As used herein, the term “fin field-effect transistor (FinFET)” refers to a MOSFET transistor built on a substrate where the gate is placed on two or three sides of the channel, forming a double- or triple-gate structure. FinFET devices have been given the generic name FinFETs because the channel region forms a “fin” on the substrate. FinFET devices have fast switching times and high current density.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm.

The embodiments of the disclosure are described by way of the Figures, which illustrate devices (e.g., transistors) and processes for forming transistors in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure are described with reference to the Figures. In the method of one or more embodiments, transistors, e.g., MOSFETS, and the like, are fabricated. One or more embodiments advantageously provides methods and structures to achieve low voltage (LV) and high voltage (HV) scale-down by suppressing the short channel effect of LV as well as increasing breakdown voltage of HV transistor. In one or more embodiments, advantageously provided is a raised highly doped structure for LV transistor and vertical n-drift regions for HV transistor by using epitaxial silicon (epi-Si) growth in contacts regions. The methods and structures of one or more embodiments advantageously make scale-down of LV transistors by allowing them to endure higher thermal budget. Thus, higher epitaxial growth temperatures can be used to lead to higher growth rates.

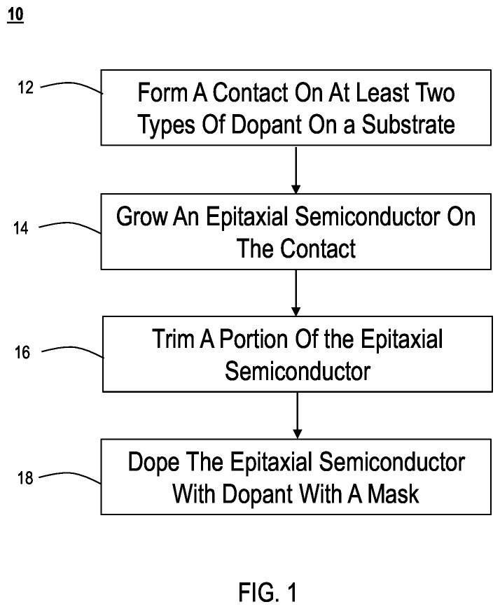

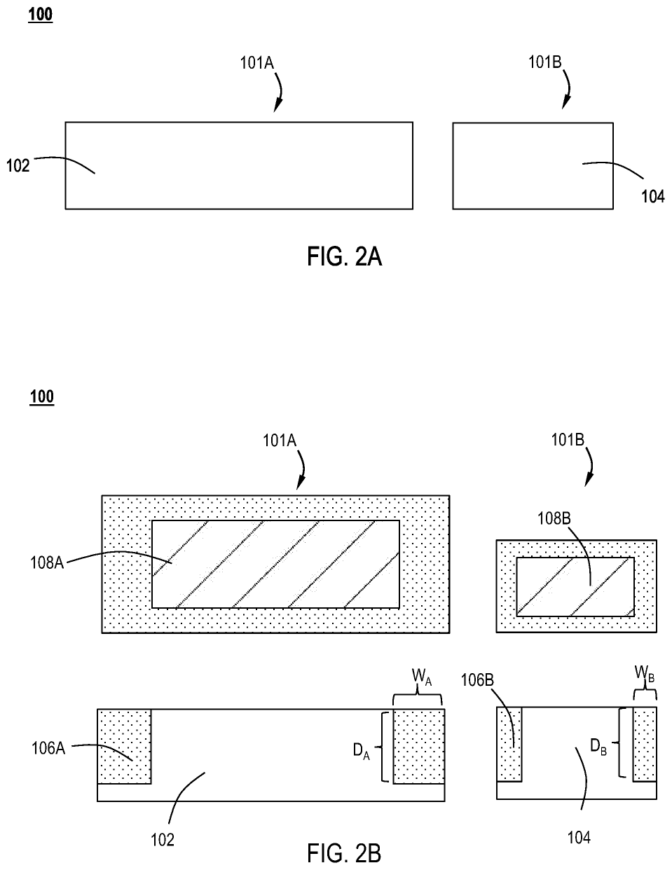

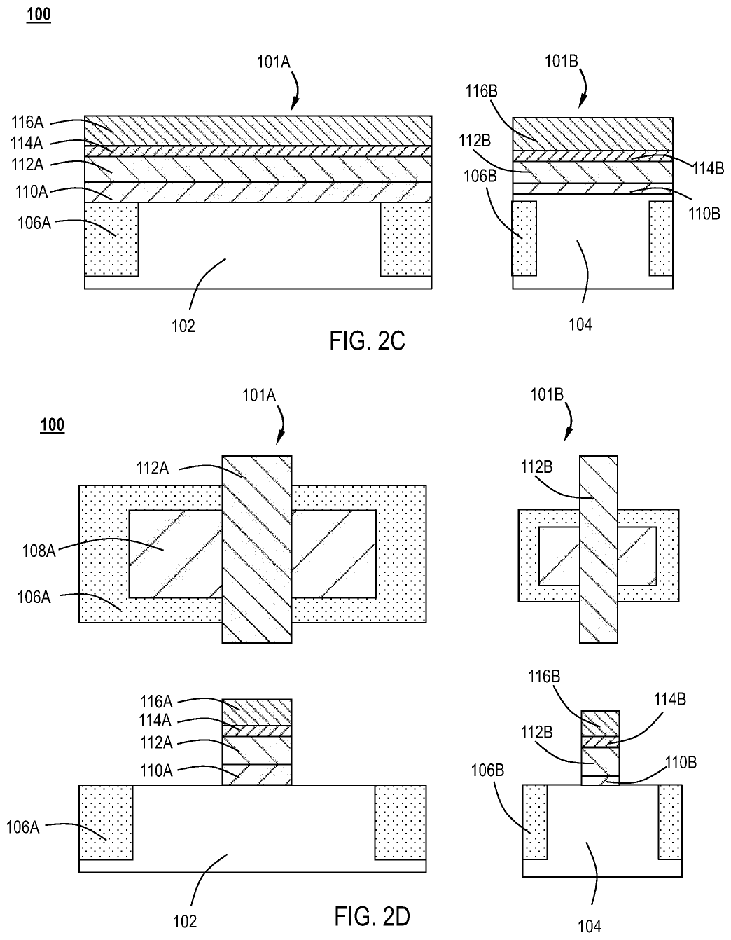

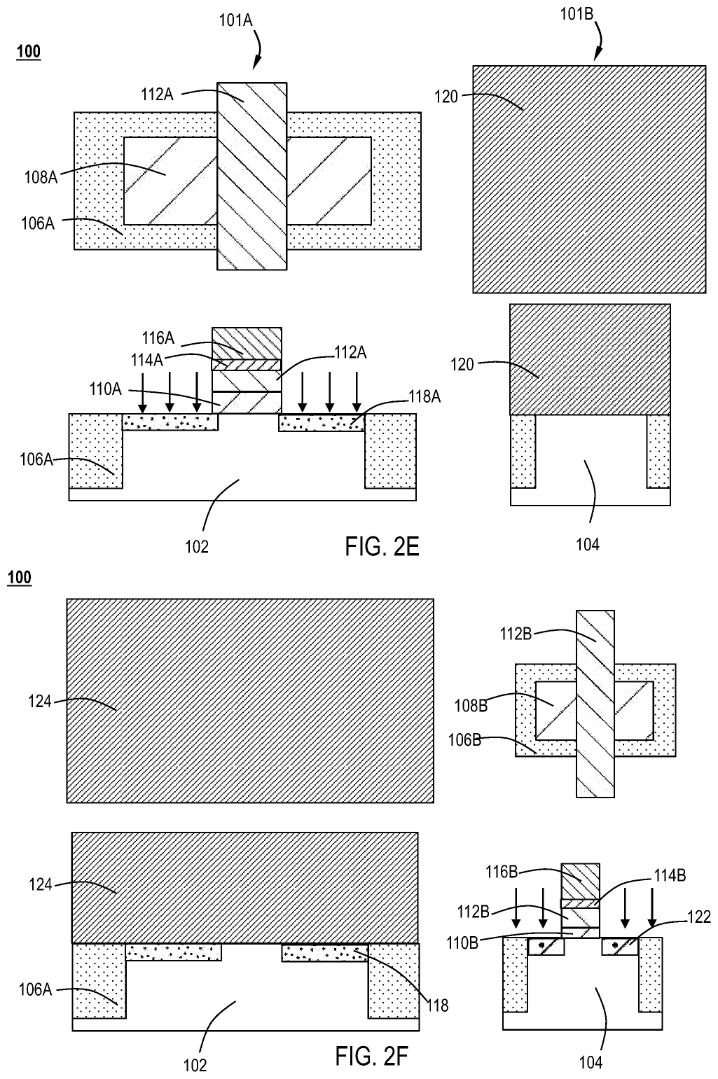

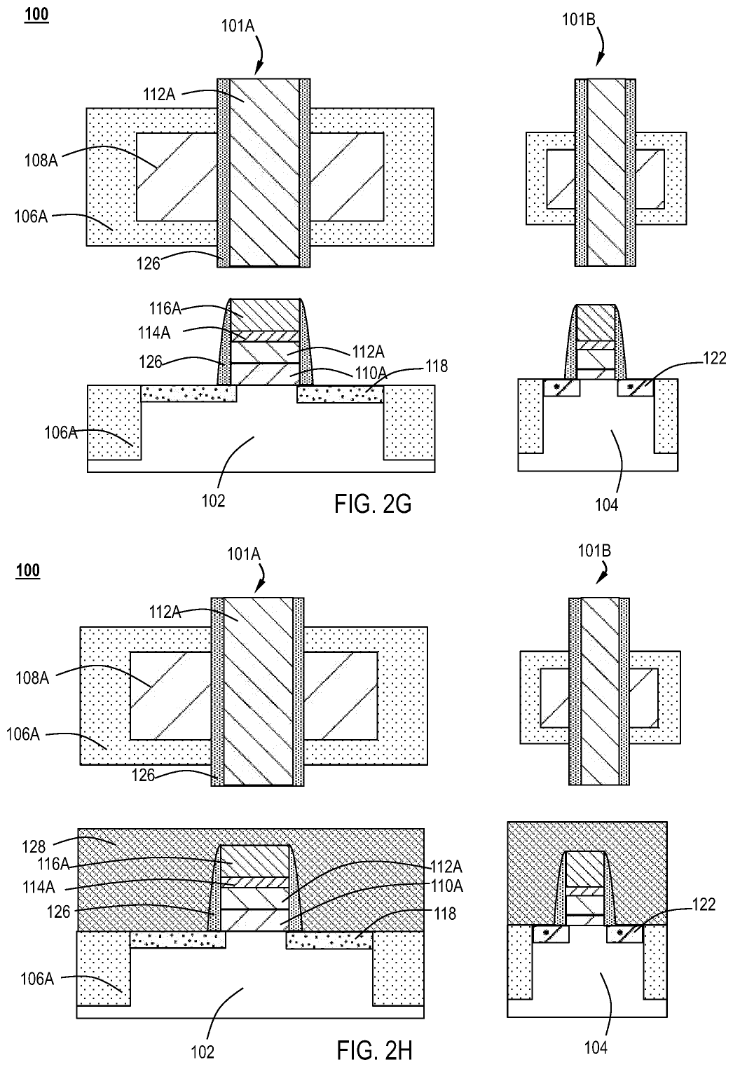

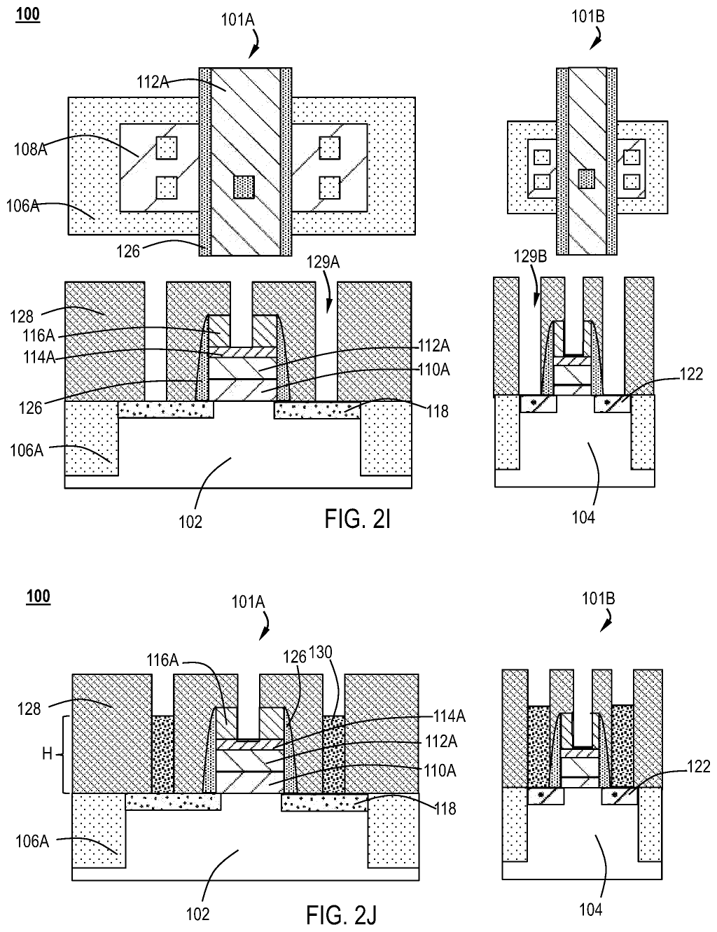

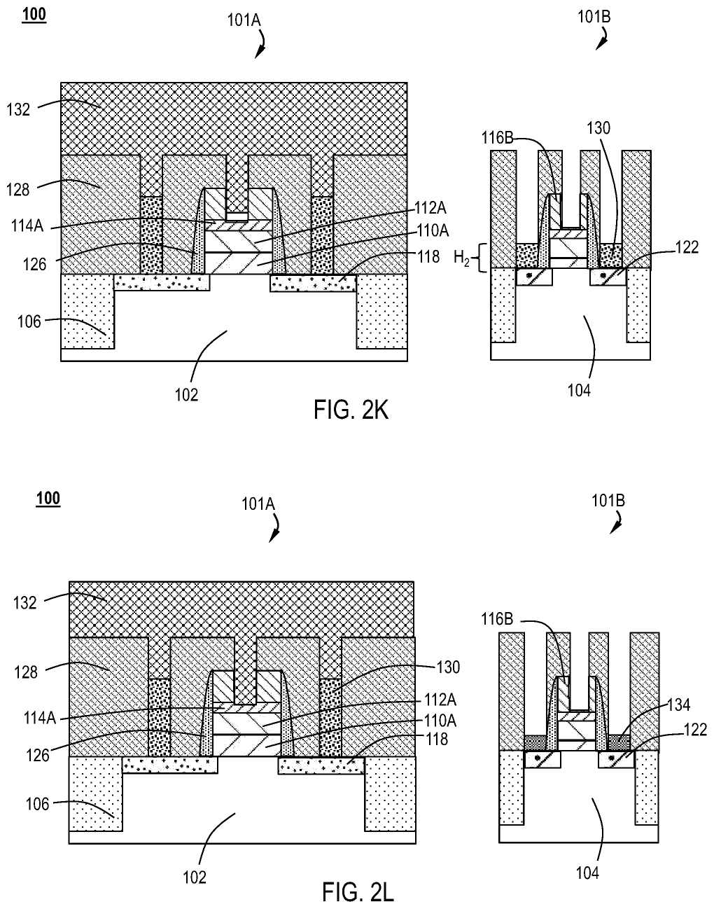

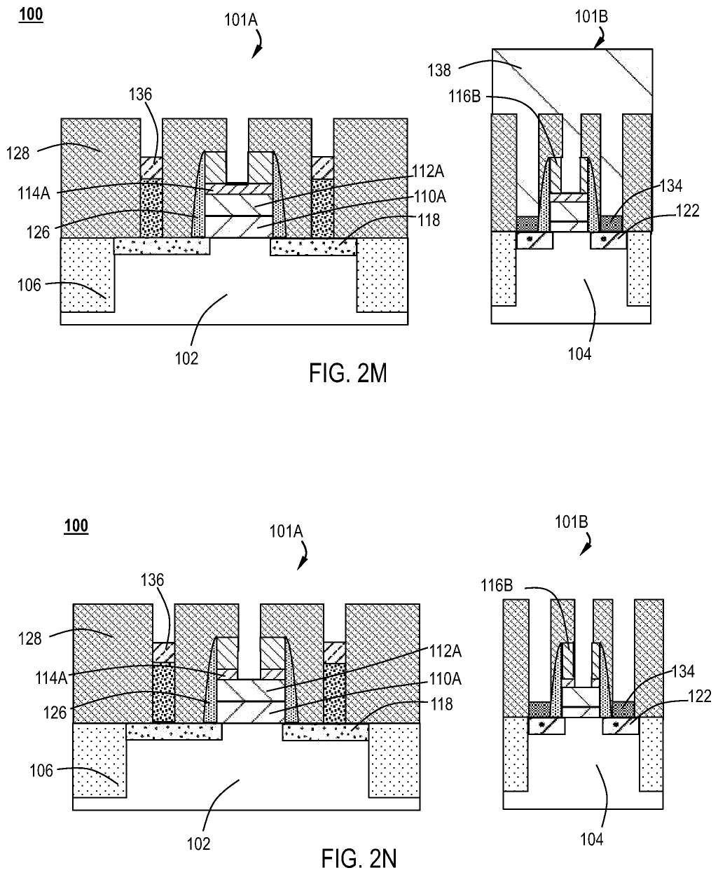

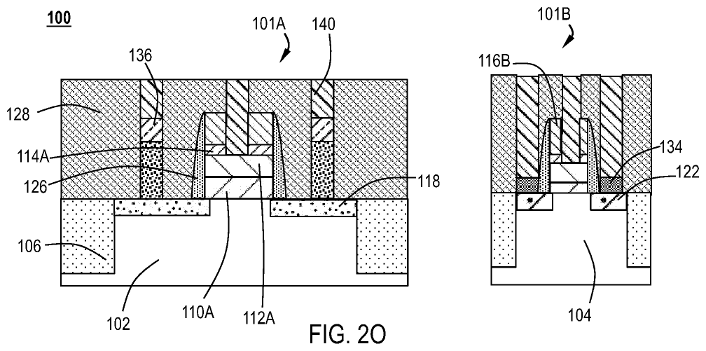

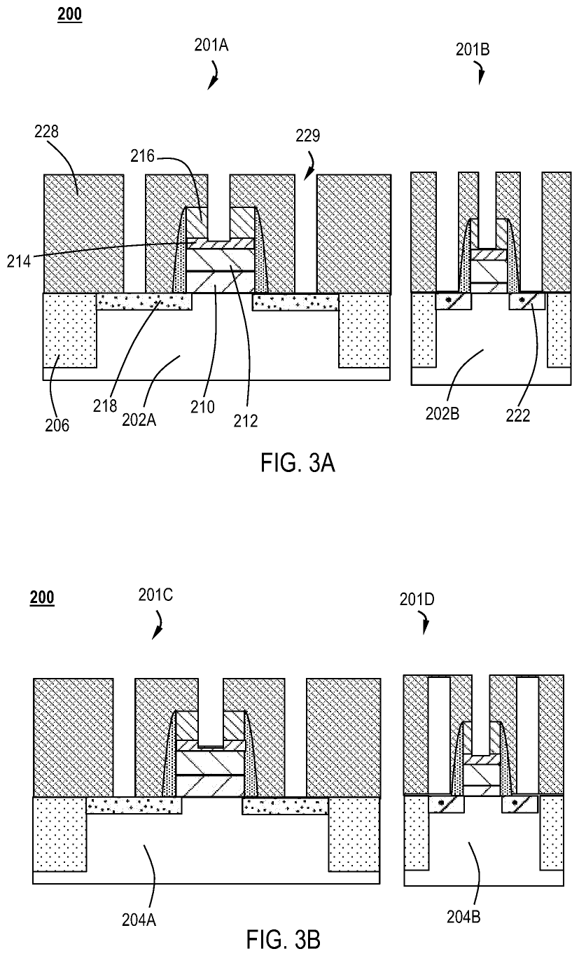

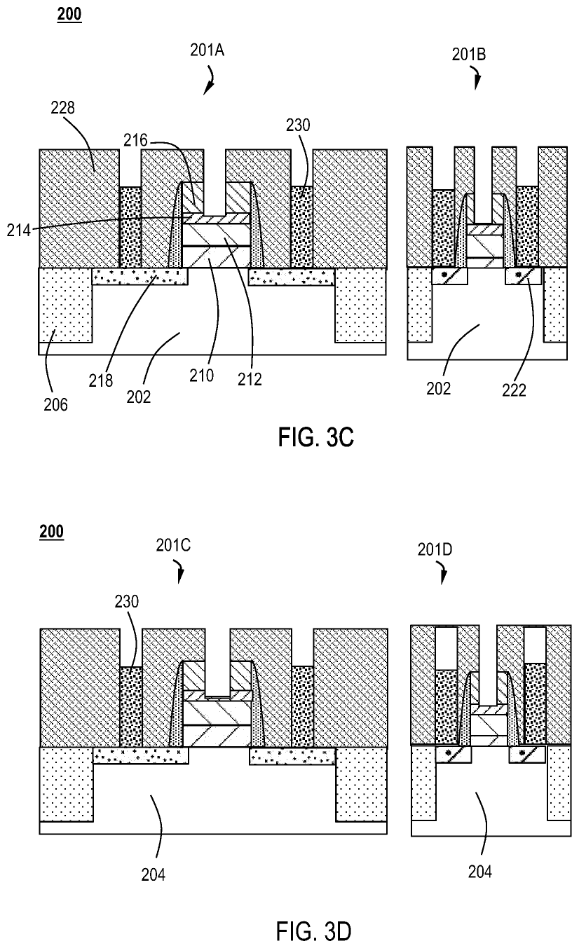

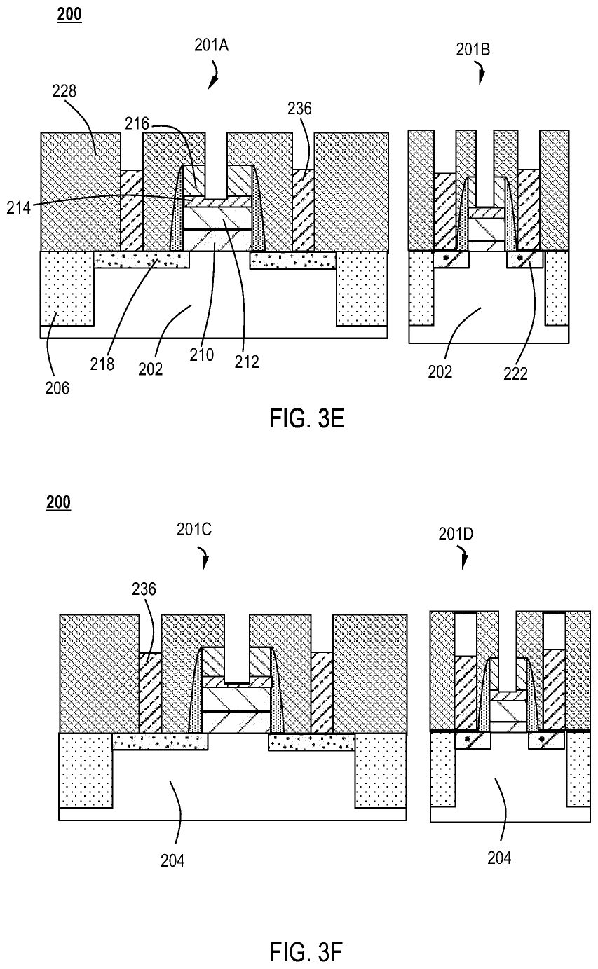

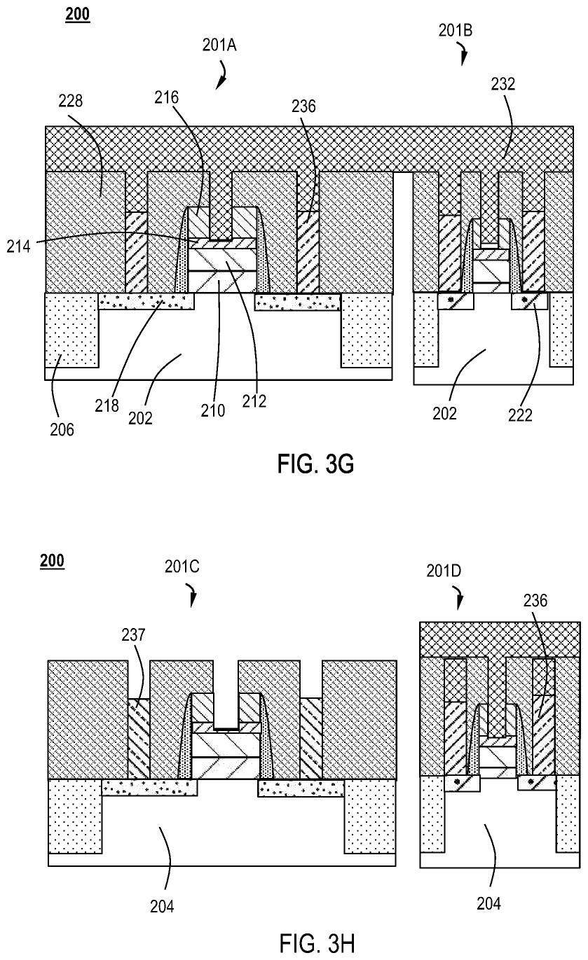

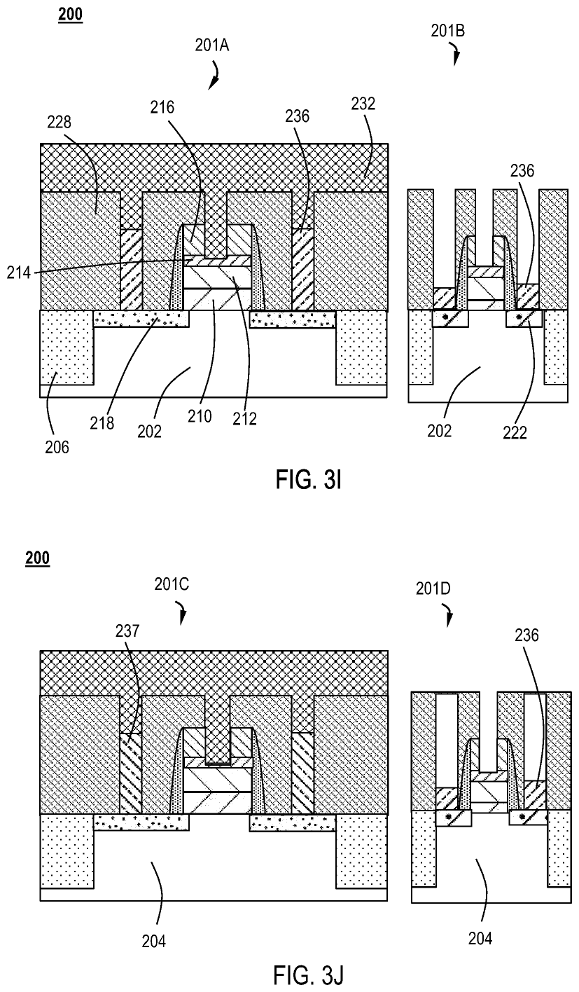

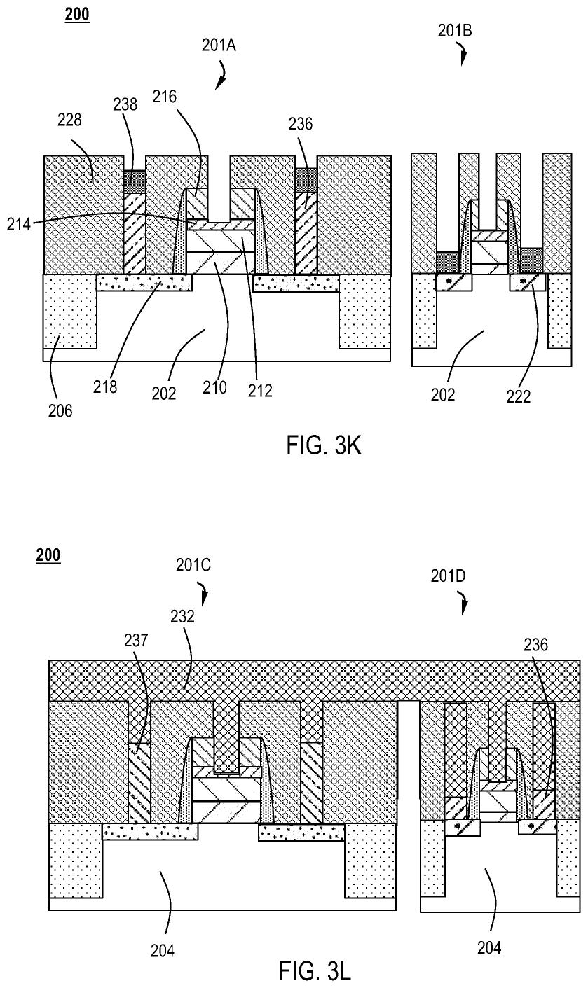

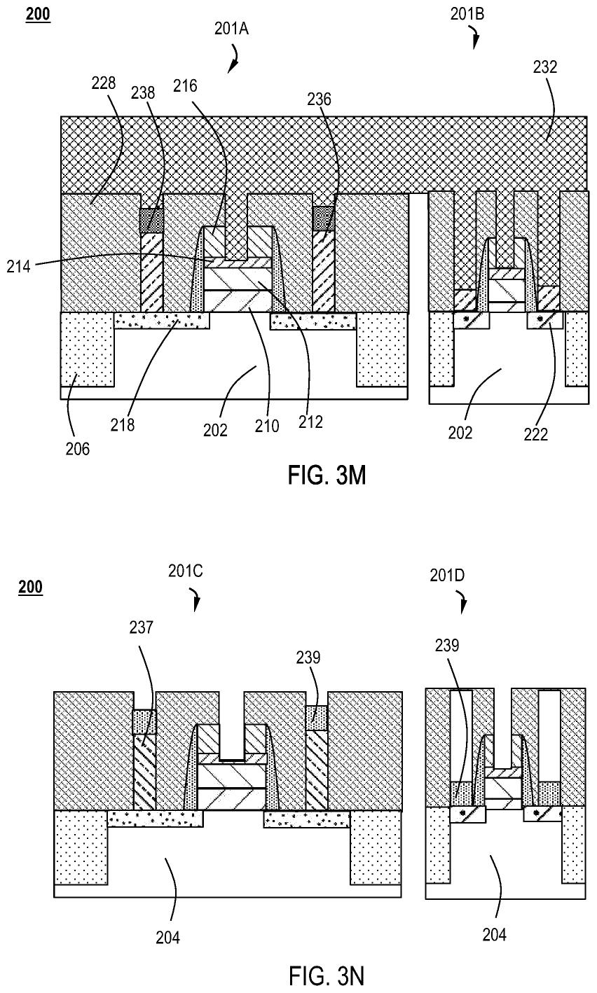

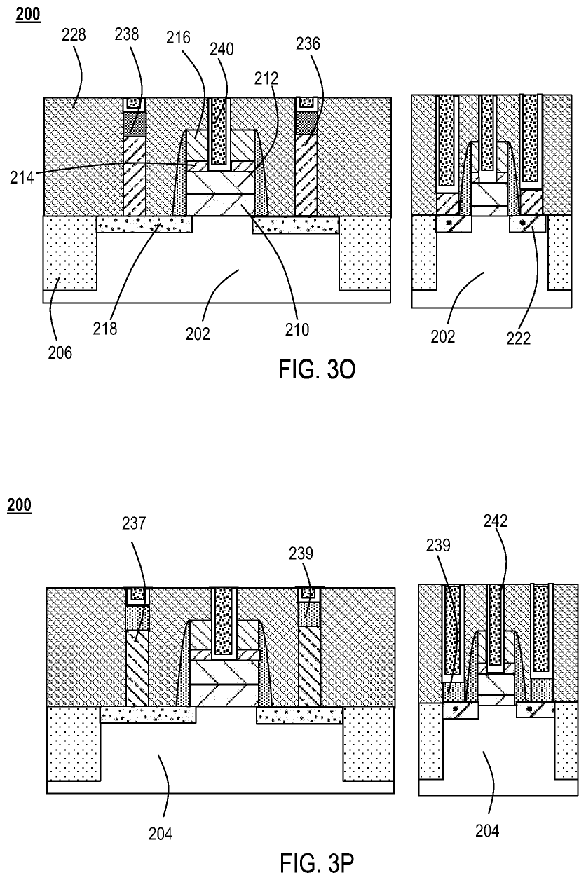

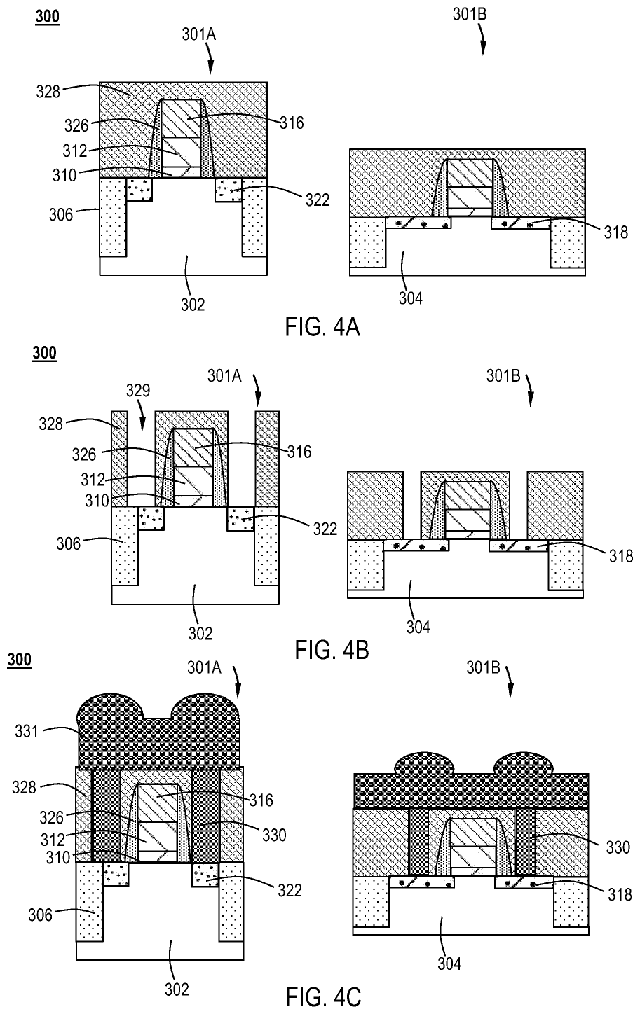

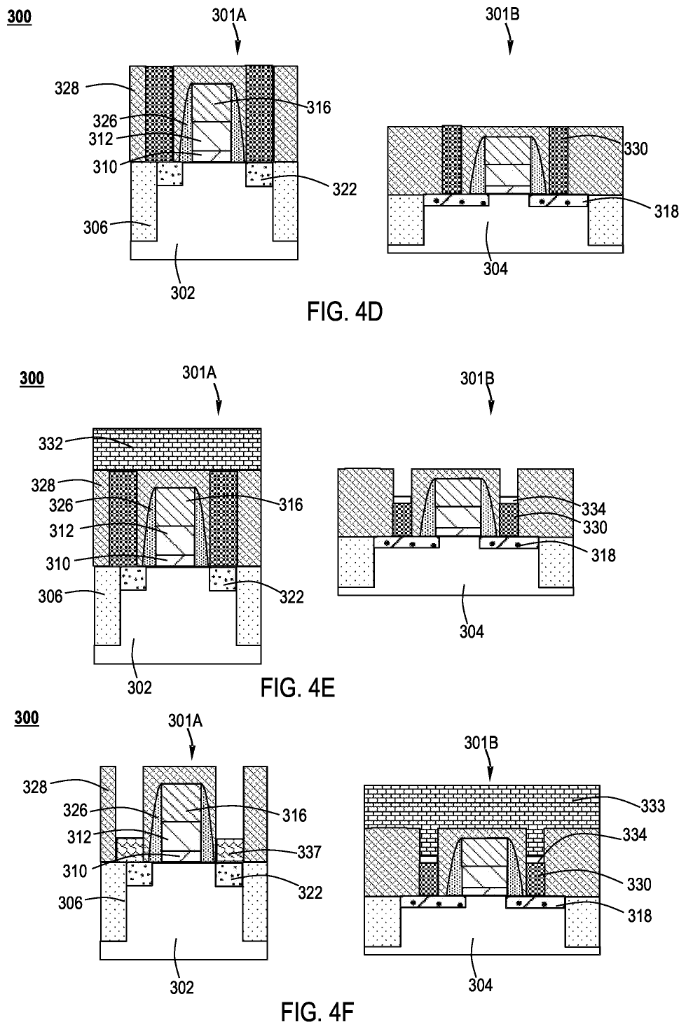

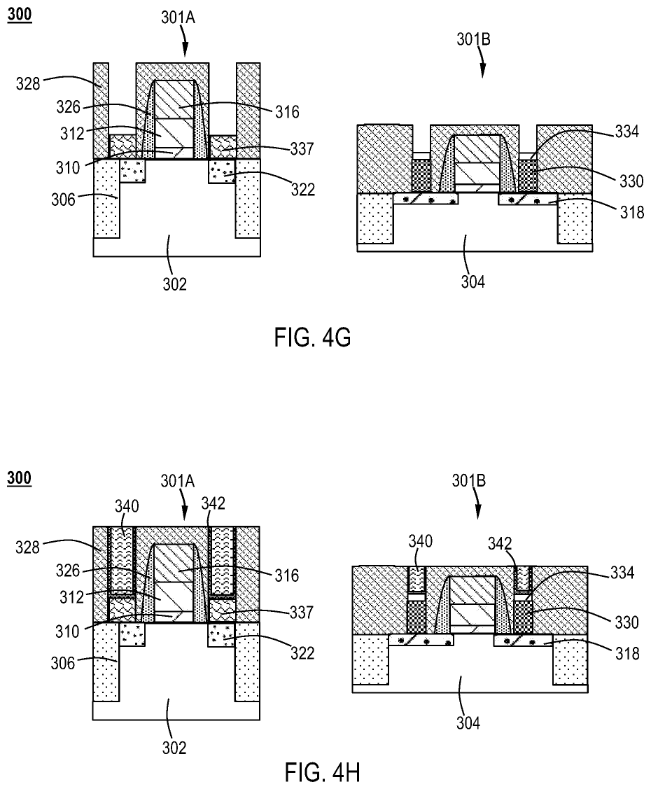

FIG. 1 illustrates the process flow diagram for a method 10 for forming a semiconductor device in accordance with some embodiments of the present disclosure. FIGS. 2A-2O depict the stages of fabrication of an n-type high voltage transistor and a p-type low-voltage transistor semiconductor structure in accordance with the process flow of FIG. 1. FIGS. 3A-3P depict the stages of fabrication of transistors in NAND flash memory in accordance with the process flow of FIG. 1. FIGS. 4A-4G depict PMOSFET AND NMOSFET, which have patterned gate and gate dielectrics along with lightly doped drain (LDD) regions.

The method 10 of forming a semiconductor device is described below with respect to FIGS. 2A-2O, FIGS. 2A-2O are cross-sectional views depicting the stages of fabrication of an n-type high voltage transistor and a p-type low-voltage transistor semiconductor structure according to one or more embodiments. The method 10 of FIG. 1 may be part of a multi-step fabrication process of a semiconductor device. Accordingly, the method 10 of FIG. 1 may be performed in any suitable process chamber coupled to a cluster tool. The cluster tool may include process chambers for fabricating a semiconductor device, such as chambers configured for etching, deposition, physical vapor deposition (PVD), chemical vapor deposition (CVD), oxidation, epitaxy, or any other suitable chamber used for the fabrication of a semiconductor device.

Referring to FIG. 1, the method 10 of forming a semiconductor device 100 begins at operation 12, by forming a contact on at least two types of dopant on a substrate. At operation 14, an epitaxial semiconductor is grown on the contact. at operation 16, a portion of the epitaxial semiconductor is trimmed. At operation 18, the epitaxial semiconductor is doped with a dopant using a mask.

Referring to FIGS. 2A through 2O, in one or more embodiments, a cross-sectional view of a semiconductor device 100 having n-type transistor 100A and a p-type transistor 100B. The n-type transistor 100A includes a first well region 102 of a first conductivity type, and the p-type transistor 100B includes a second well region 104 of a second conductivity type.

With reference to FIG. 2B, the n-type transistor 100A may include a p-type well region 102 with an active region 108A defined by isolation regions 106A. The p-type transistor 100B may include an n-type well region 104 with an active region 108B defined by isolation regions 106B. In one or more embodiments, the shallow trench isolation regions 106A, 106B may be defined by a width, W, and a depth, D. In one or more embodiments, the width of the isolation region 106A is in a range of from 0.05 μm to 5 μm and the depth is in a range of from 0.02 μm to 1.0 μm. In one or more embodiments, the width of the isolation region 106B is in a range of from 0.02 μm to 0.5 μm and the depth is in a range of from 0.02 μm to 1.0 μm.

As used herein, the term “shallow trench isolation (STI)” refers to an integrated circuit feature which prevents current leakage. In one or more embodiments, STI is created by depositing one or more dielectric materials (such as silicon dioxide) to fill a trench or opening and removing the excess dielectric using a technique such as chemical-mechanical planarization.

With reference to FIG. 2C, in one or more embodiments, transistor layers are deposited above the isolation regions 106A, 106B.

The transistor layers deposited on the n-type transistor 101A may include one or more of a gate oxide layer 110A, a gate 112A, an etch stop layer 114A, and a hard mask 116A. The gate oxide layer 110A may comprise any suitable material. In one or more embodiments, the gate oxide layer 110A comprises one or more of silicon oxide (SiOx) or silicon oxynitride (SiON). The gate oxide layer 110A may have any suitable thickness. In one or more embodiments, the gate oxide layer 110A has a thickness in a range of from 20 nm to 100 nm.

In one or more embodiments, the gate 112A may comprise any suitable material. In one or more embodiments, the gate 112A comprises one or more of a nitride (N) with silicon (Si), a nitride (N) with tungsten silicon (WSi), or a nitride (N) with silicon tungsten (SiW). The gate 112A may have any suitable thickness. In one or more embodiments, the gate 112A has a thickness in a range of from 20 nm to 100 nm.

In one or more embodiments, the etch stop layer 114A may comprise any suitable material. In some embodiment, the etch stop layer 114A can include any silicon-based material except silicon oxide (SiOx). In one or more embodiments, the etch stop layer 114A is selected from one or more of silicon nitride (SiN), silicon oxynitride (SiON), silicon carbonitride (SiCN), silicon boronitride (SiBN), silicon boride (SiB), and the like. The etch stop layer 114A may have any suitable thickness. In one or more embodiments, the etch stop layer 114A has a thickness in a range of from 1 nm to 50 nm.

In one or more embodiments, the hard mask 116A may comprise any suitable material. In one or more embodiments, the hard mask 116A comprises a moderate temperature oxide. In one or more embodiments, the hard mask 116A may have any suitable thickness. In one or more embodiments, the hard mask 116A has a thickness in a range of from 50 nm to 200 nm.

The transistor layers deposited on the p-type transistor 101B may include one or more of a gate oxide layer 110B, a gate 112B, an etch stop layer 114B, and a hard mask 116B. The gate oxide layer 110B may comprise any suitable material. In one or more embodiments, the gate oxide layer 110B comprises one or more of silicon oxide (SiOx) or silicon oxynitride (SiON). The gate oxide layer 110B may have any suitable thickness. In one or more embodiments, the gate oxide layer 110B has a thickness in a range of from 2 nm to 10 nm.

In one or more embodiments, the gate 112B may comprise any suitable material. In one or more embodiments, the gate 112B comprises one or more of a nitride (N) with silicon (Si), a nitride (N) with tungsten silicon (WSi), or a nitride (N) with silicon tungsten (SiW). The gate 112B may have any suitable thickness. In one or more embodiments, the gate 112B has a thickness in a range of from 20 nm to 100 nm.

In one or more embodiments, the etch stop layer 114B may comprise any suitable material. In some embodiment, the etch stop layer 114B can include any silicon-based material except silicon oxide (SiOx). In one or more embodiments, the etch stop layer 114B is selected from one or more of silicon nitride (SiN), silicon oxynitride (SiON), silicon carbonitride (SiCN), silicon boronitride (SiBN), silicon boride (SiB), and the like. The etch stop layer 114B may have any suitable thickness. In one or more embodiments, the etch stop layer 114B has a thickness in a range of from 1 nm to 50 nm.

In one or more embodiments, the hard mask 116B may comprise any suitable material. In one or more embodiments, the hard mask 116B comprises a moderate temperature oxide. In one or more embodiments, the hard mask 116B may have any suitable thickness. In one or more embodiments, the hard mask 116B has a thickness in a range of from 50 nm to 200 nm.

With reference to FIG. 2D, the transistors 101A, 101B are patterned to form the gate stacks 112A, 112B.

Referring to FIG. 2E, the p-type transistor 101B is covered with a photoresist 120, and a lightly doped region 118A is formed on the first well 102. The lightly doped region 118A may be doped with any suitable material known to the skilled artisan. In one or more embodiments, the lightly doped region 118A is doped with one or more of phosphorus (P) or arsenic (As) to form an N-MOSFET. In one or more embodiments, the lightly doped region 118A has an Rp in a range of from 0.1 μm to 0.5 μm. The dopant density may be in a range of from 1E14 cm³ to 1E17 cm³. The photoresist 120 is then removed.

With reference to FIG. 2F, the N-MOSFET 101A is then covered with a photoresist 124, and a lightly doped region 122 is formed on the second well 104 of the p-type transistor 101B. The lightly doped region 122 may be doped with any suitable material known to the skilled artisan. In one or more embodiments, the lightly doped region 122 is doped with one or more of boron (B) or boron fluoride (BF₂) to form a P-MOSFET. In one or more embodiments, the lightly doped region 122 has an Rp in a range of from 0.1 μm to 0.5 μm. The dopant density may be in a range of from 1E14 cm³ to 1E17 cm³. The photoresist 124 is then removed.

Referring to FIG. 2G, a gate spacer 126 is formed on the gate stacks 112A, 112B. The gate spacer 126 may comprise any suitable material known to the skilled artisan. In one or more embodiments, the gate spacer 126 comprises silicon oxide (SiOx) or silicon oxynitride (SiOX). The gate spacer 126 may have any suitable thickness. In one or more embodiments, the gate spacer 126 has a thickness in a range of from 20 nm to 200 nm.

With reference to FIG. 2H, an interlayer dielectric layer 128 is then deposited around the gate stacks 112A, 112B on the isolation regions 106A, 106B, and on the doped regions 118, 122. The interlayer dielectric layer 128 may comprise any suitable material known to the skilled artisan. In one or more embodiments, the interlayer dielectric layer 128 comprises silicon oxide (SiOx). The interlayer dielectric layer 128 may have any suitable thickness. In some embodiments, the interlayer dielectric layer 128 has a thickness in a range of from 0.3 μm to 1.0 μm.

Referring to FIG. 2I, the interlayer dielectric layer 128 is patterned to form contact openings 129A, 129B over the source/drain region and in the gate stacks. In one or more embodiments, the number of contact openings 129A, 129B in the source/drain regions may be more than one to reduce contact resistance. The interlayer dielectric layer 128 may be patterned using any suitable technique known to the skilled artisan. In one or more embodiments, the interlayer dielectric layer 128 is patterned using reactive ion etching (RIE). In one or more embodiments, the contact openings 129A, 129B are formed in the gate stacks 112A, 112B stopping at the etch stop layer 114A, 114B.

The contact openings 129A, 129B may have any suitable critical dimension. In one or more embodiments, the critical dimension of the contact openings 129A, 129B is in a range of from 50 nm to 200 nm.

With reference to FIG. 2J, epitaxial silicon 130 (epi-Si) is grown selectively in the contact openings 129A, 129B over the source/drain lightly doped regions 118, 122. During the epitaxial growth, the gate stack 112A, 112B contact openings are protected by the etch stop layer 114A, 114B, so no epitaxial-silicon 130 forms in the gate stack contact opening.

The epitaxial silicon 130 may have any suitable height, h. In some embodiments, the height, h, of the epitaxial silicon is in a range of from 500 nm to 1000 nm.

In one or more embodiments, silicon (Si), silicon germanium (SiGe), silicon doped with carbon (Si:C), and combinations thereof, while neither donor nor acceptor, are doped. Silicon sources for epitaxial growth include silicon tetrachloride, dichlorosilane (SiH, CI), and silane (SiH). In one or more embodiments, the temperature for epitaxial silicon growth is in a range of from 400° C. to 1000° C., or in a range of from 550° C. to 1000° C.

Referring to FIG. 2K, a photoresist 132 is formed or coated on the interlayer dielectric layer 128 of the n-type transistor 101A. The photoresist 132 may have any suitable thickness. In one or more embodiments, the photoresist 132 has a thickness in a range of from 0.1μ to 2 μm.

Without intending to be bound by theory, the high voltage n-transistor 101A typically needs to have a high voltage breakdown voltage (BV) of about 30 V, while other types of transistors have a lower breakdown voltage of less than 10V. Thus, other transistors do not need vertical lightly doped regions.

In one or more embodiments, the epitaxial silicon 130 of the p-type transistor 101B does not require a high breakdown voltage is then trimmed to obtain a height, H₂, in a range of from 10 nm to 50 nm. The epitaxial silicon 130 may be etched by any suitable technique known to the skilled artisan. In one or more embodiments, the epitaxial silicon 130 is etched using wet or dry etching. The etch process may be a directional etch.

In some embodiments, the dry etch process may include a conventional plasma etch, or a remote plasma-assisted dry etch process, where the device is exposed to H₂, NF₃, and/or NH₃ plasma species, e.g., plasma-excited hydrogen and fluorine species. For example, in some embodiments, the device may undergo simultaneous exposure to H₂, NF₃, and NH₃ plasma. The etch process of one or more embodiments may be performed in any suitable preclean chamber, which may be integrated into one of a variety of multi-processing platforms. The wet etch process may include a hydrofluoric (HF) acid last process, i.e., the so-called “HF last” process, in which HF etching of surface is performed that leaves surface hydrogen-terminated. Alternatively, any other liquid-based pre-epitaxial pre-clean process may be employed. In some embodiments, the process comprises a sublimation etch for native oxide removal. The etch process can be plasma or thermally based. The plasma processes can be any suitable plasma (e.g., conductively coupled plasma, inductively coupled plasma, microwave plasma).

In some embodiments, the wet etch process includes tetramethyl ammonium hydroxide (TMAH) with a high etch selectivity against SiN and SiO.

With reference to FIG. 2L, the etched portion of the epitaxial silicon 130 is doped with a P-type material to form a highly doped region 134 of the p-type transistor 101B. The p-type material may be any suitable material known to the skilled artisan. In one or more embodiments, the p-type material used for forming the doped region 134 comprises one or more of B or BF₂. The density of the highly doped region 134 may be in a range of from 1E19 cm⁻³ to 5E20 cm⁻³. The implant energy of the highly doped region 134 may be in a range of from 5 keV to 30 keV. In one or more embodiments, in order to suppress the diffusion of the dopant into the substate, carbon may be co-implanted with the dopant. After the highly doped region 134 is formed, the photoresist 132 is removed from the n-type transistor 101A.

With reference to FIG. 2M, a photoresist 138 is formed on the p-type transistor 101B. In one or more embodiments, a portion of the epitaxial silicon 130 of the n-type transistor 101A is doped with an n-type material to form a highly doped region 136 of the n-type transistor 101A. The n-type material may be any suitable material known to the skilled artisan. In one or more embodiments, the n-type material used for forming the doped region 136 comprises one or more of P or As. In one or more embodiments, when phosphorus (P) is used as the dopant, the density of the highly doped region 136 may be in a range of from 1E17 cm⁻³ to 5E18 cm⁻³, and the implant energy of the highly doped region 136 may be in a range of from 5 keV to 20 keV. In one or more embodiments, when arsenic (As) is used as the dopant, the density of the highly doped region 136 may be in a range of from 1E20 cm⁻³ to 5E20 cm⁻³, and the implant energy of the highly doped region 136 may be in a range of from 5 keV to 20 keV. After the highly doped region 136 is formed, the photoresist 138 is removed from the p-type transistor 101B. The photoresist 138 may be removed by any suitable means known to the skilled artisan. In one or more embodiments, the photoresist 138 may be removed by one or more of ashing or stripping.

With reference to FIG. 2N, the etch stop layer 114A, 114B on top of the gate 112A, 112B is removed. The etch stop layer 114A, 114B can be removed by any suitable means known to the skilled artisan. In one or more embodiments, the etch stop layer 114A, 114B in the gate contact region is removed by one or more of wet etching and dry etching without the use of a mask. Wet etching may involve the use of hot phosphoric acid. Dry etching may comprise reactive ion etching using gas chemistry including a gas mixture of carbon tetrafluoride (CF₄) and oxygen (O₂).

Referring to FIG. 2O, in one or more embodiments, the contact regions on the source/drain and gate region are filled with a contact metal fill to form a contact metal 140. The metal fill 140 may comprise any suitable material. In some embodiments, the contact region is first filled with a barrier metal followed by the metal fill 140. The contact metal 140 may comprise one or more of tungsten (W), molybdenum (Mo), titanium nitride (TiN), tantalum nitride (TaN), cobalt (Co) ruthenium (Ru), and copper (Cu).

Referring to FIGS. 3A through 3P, in one or more embodiments, a cross-sectional view of a semiconductor device 200 having different types of transistors in NAND flash memory—high voltage n-transistor 201A, high voltage p-transistor 201C, low voltage n-transistor 201B, and low voltage p-transistor 201D. The high voltage n-type transistor 201A includes a first well region 202A of a first conductivity type, and the low voltage n-transistor 201B includes a second well region 202B of the first conductivity type. The high voltage p-type transistor 201C includes a third well region 204A of a second conductivity type, and the low voltage p-transistor 201D includes a fourth well region 204B of the second conductivity type.

With reference to FIGS. 3A and 3B, each transistor 201A, 201B, 201C, 201D may include a well region 202A, 202B, 204A, 204B with an active region defined by isolation regions 206. In one or more embodiments, the shallow trench isolation regions 206 may be defined by a width, W, and a depth, D. In one or more embodiments, the width of the isolation region 106 of the high voltage transistors 201A, 201C is in a range of from 0.05 μm to 5 μm and the depth is in a range of from 0.02 μm to 1.0 μm. In one or more embodiments, the width of the isolation region 206 of the low voltage transistors 201B, 201D is in a range of from 0.02 μm to 0.5 μm and the depth is in a range of from 0.02 μm to 1.0 μm.

With reference to FIGS. 3A-3B, in one or more embodiments, transistor layers are deposited above the isolation region 206.

The transistor layers deposited on each transistor 201A, 201B, 201C, 201D may include one or more of a gate oxide layer 210, a gate 212, an etch stop layer 214, and a hard mask 216. The gate oxide layer 210 may comprise any suitable material. In one or more embodiments, the gate oxide layer 210 comprises one or more of silicon oxide (SiOx) or silicon oxynitride (SiON). The gate oxide layer 210 may have any suitable thickness. In one or more embodiments, the gate oxide layer 210 has a thickness in a range of from 20 nm to 100 nm.

In one or more embodiments, the gate 212 may comprise any suitable material. In one or more embodiments, the gate 212 comprises one or more of a nitride (N) with silicon (Si), a nitride (N) with tungsten silicon (WSi), or a nitride (N) with silicon tungsten (SiW). The gate 212 may have any suitable thickness. In one or more embodiments, the gate 212 has a thickness in a range of from 20 nm to 100 nm.

In one or more embodiments, the etch stop layer 214 may comprise any suitable material. In some embodiment, the etch stop layer 214 can include any silicon-based material except silicon oxide (SiOx). In one or more embodiments, the etch stop layer 214 is selected from one or more of silicon nitride (SiN), silicon oxynitride (SiON), silicon carbonitride (SiCN), silicon boronitride (SiBN), silicon boride (SiB), and the like. The etch stop layer 214 may have any suitable thickness. In one or more embodiments, the etch stop layer 214 has a thickness in a range of from 1 nm to 50 nm.

In one or more embodiments, the hard mask 216 may comprise any suitable material. In one or more embodiments, the hard mask 216 comprises a moderate temperature oxide. In one or more embodiments, the hard mask 216 may have any suitable thickness. In one or more embodiments, the hard mask 216 has a thickness in a range of from 50 nm to 200 nm.

With reference to FIGS. 3A-3B, the transistors 201A, 201B, 201C, 201D are patterned to form the gate stacks, as described above with respect to transistors 101A and 101B.

In one or more embodiments, a gate spacer 226 is formed on the gate stacks. The gate spacer 226 may comprise any suitable material known to the skilled artisan. In one or more embodiments, the gate spacer 226 comprises silicon oxide (SiOx) or silicon oxynitride (SiOX). The gate spacer 226 may have any suitable thickness. In one or more embodiments, the gate spacer 226 has a thickness in a range of from 20 nm to 200 nm.

In one or more embodiments, an interlayer dielectric layer 228 is then deposited around the gate stacks on the isolation regions 206, and on the doped regions 218, 222. The interlayer dielectric layer 228 may comprise any suitable material known to the skilled artisan. In one or more embodiments, the interlayer dielectric layer 228 comprises silicon oxide (SiOx). The interlayer dielectric layer 228 may have any suitable thickness. In some embodiments, the interlayer dielectric layer 228 has a thickness in a range of from 0.3 μm to 1.0 μm.

Referring to FIGS. 3A and 3B, the interlayer dielectric layer 228 is patterned to form contact openings 229 over the source/drain region and in the gate stacks. In one or more embodiments, the number of contact openings 229 in the source/drain regions may be more than one to reduce contact resistance. The interlayer dielectric layer 228 may be patterned using any suitable technique known to the skilled artisan. In one or more embodiments, the interlayer dielectric layer 228 is patterned using reactive ion etching (RIE). In one or more embodiments, the contact openings 229 are formed in the gate stacks stopping at the etch stop layer 214.

The contact openings 229 may have any suitable critical dimension. In one or more embodiments, the critical dimension of the contact openings 229 is in a range of from 50 nm to 200 nm.

With reference to FIGS. 3C-3D, epitaxial silicon 230 (epi-Si) is grown selectively in the contact openings 229 over the source/drain lightly doped regions 218, 222. During the epitaxial growth, the gate stack contact openings are protected by the etch stop layer 214, so no epitaxial-silicon 230 forms in the gate stack contact opening.

The epitaxial silicon 230 may have any suitable height, h. In some embodiments, the height, h, of the epitaxial silicon in the source/drain region is in a range of from 500 nm to 1000 nm.

In one or more embodiments, silicon (Si), silicon germanium (SiGe), silicon doped with carbon (Si:C), and combinations thereof, while neither donor nor acceptor, are doped. Silicon sources for epitaxial growth include silicon tetrachloride, dichlorosilane (SiH, CI), and silane (SiH). In one or more embodiments, the temperature for epitaxial silicon growth is in a range of from 400° C. to 1000° C., or in a range of from 550° C. to 1000° C.

Referring to FIGS. 3E and 3F, the epitaxial silicon 230 is doped with an n-type material to form an n-doped epitaxial silicon 236. The n-type material may be any suitable material known to the skilled artisan. In one or more embodiments, the n-type material used for forming the doped epitaxial silicon 236 comprises one or more of P or As. In one or more embodiments, when phosphorus (P) is used as the dopant, the density of the highly doped epitaxial silicon 236 may be in a range of from 1E17 cm⁻³ to 5E18 cm⁻³, and the implant energy of the highly doped region 236 may be in a range of from 5 keV to 20 keV. In one or more embodiments, when arsenic (As) is used as the dopant, the density of the highly doped region 236 may be in a range of from 1E20 cm⁻³ to 5E20 cm⁻³, and the implant energy of the highly doped region 236 may be in a range of from 5 keV to 20 keV.

Referring to FIGS. 3G and 3H, a photoresist 232 is formed or coated on the interlayer dielectric layer 228 of the high voltage n-type transistor 201A, on the low voltage n-type transistor 201B, and on the low voltage p-type transistor 201D, but not on the high voltage p-type transistors 201C. The photoresist 232 may have any suitable thickness. In one or more embodiments, the photoresist 232 has a thickness in a range of from 0.1μ to 2 μm.

In one or more embodiments, the epitaxial silicon 230 of the high voltage p-type transistor 201C is doped with a P-type material to form a highly doped region 237 of the high voltage p-type transistor 201C. The p-type material may be any suitable material known to the skilled artisan. In one or more embodiments, the p-type material used for forming the doped region 237 comprises one or more of B or BF₂. The density of the highly doped region 237 may be in a range of from 2E17 cm⁻³ to 1E19 cm⁻³. In one or more embodiments, the dosing of p-dopant is thought to compensate for the doping of the n-doped region 236. After the highly doped region 237 is formed, the photoresist 232 is removed from the low voltage p-type transistor 201D. The photoresist 232 may be removed by any suitable means known to the skilled artisan. In one or more embodiments, the photoresist 232 may be removed by one or more of ashing or stripping.

With reference to FIGS. 3I and 3J, the highly n-doped epitaxial silicon 236 of the low voltage n-type transistor 201B and the low voltage p-type transistor 201D is trimmed to obtain a height, H₂, in a range of from 10 nm to 50 nm. The epitaxial silicon 236 of the low voltage n-type transistor 201B and the low voltage p-type transistor 201D may be etched by any suitable technique known to the skilled artisan. In one or more embodiments, the epitaxial silicon 236 of the low voltage n-type transistor 201B and the low voltage p-type transistor 201D is etched using wet or dry etching. The etch process may be a directional etch.

In some embodiments, the dry etch process may include a conventional plasma etch, or a remote plasma-assisted dry etch process, where the device is exposed to H₂, NF₃, and/or NH₃ plasma species, e.g., plasma-excited hydrogen and fluorine species. For example, in some embodiments, the device may undergo simultaneous exposure to H₂, NF₃, and NH₃ plasma. The etch process of one or more embodiments may be performed in any suitable preclear chamber, which may be integrated into one of a variety of multi-processing platforms. The wet etch process may include a hydrofluoric (HF) acid last process, i.e., the so-called “HF last” process, in which HF etching of surface is performed that leaves surface hydrogen-terminated. Alternatively, any other liquid-based pre-epitaxial pre-clean process may be employed. In some embodiments, the process comprises a sublimation etch for native oxide removal. The etch process can be plasma or thermally based. The plasma processes can be any suitable plasma (e.g., conductively coupled plasma, inductively coupled plasma, microwave plasma).

In some embodiments, the wet etch process includes tetramethyl ammonium hydroxide (TMAH) with a high etch selectivity against SiN and SiO.

Referring to FIGS. 3K and 3L, the photoresist 232 is removed from the high voltage n-type transistor 201A and formed on the low voltage p-type transistor 201D. The n-doped epitaxial region 236 of the high voltage n-transistor 201A and of the low voltage n-transistor 201B are then doped with an n-type material to form a highly doped n-type region 238. The n-type material may be any suitable material known to the skilled artisan. In one or more embodiments, the n-type material used for forming the highly doped region 238 comprises one or more of P or As. In one or more embodiments, when arsenic (As) is used as the dopant, the density of the highly doped region 238 may be in a range of from 1E20 cm⁻³ to 5E20 cm⁻³, and the implant energy of the highly doped region 238 may be in a range of from 5 keV to 20 keV. After the highly doped region 238 is formed, the photoresist 232 is removed from the p-type transistors 201C and 201D. The photoresist 232 may be removed by any suitable means known to the skilled artisan. In one or more embodiments, the photoresist 232 may be removed by one or more of ashing or stripping.

With reference to FIGS. 3M and 3N, in one or more embodiments, a photoresist 232 is then formed on the n-type transistors 201A and 201B. The p-doped epitaxial region 237 of the high voltage p-transistor 201C and of the low voltage p-transistor 201D are then doped with a p-type material to form a highly doped p-type region 239. The p-type material may be any suitable material known to the skilled artisan. In one or more embodiments, the p-type material used for forming the highly doped region 239 comprises one or more of B or BF₂. In one or more embodiments, when BF₂ is used as the dopant, the density of the highly doped region 239 may be in a range of about 1E21 cm⁻³, and the implant energy of the highly doped region 239 may be in a range of from 5 keV to 20 keV. After the highly doped region 239 is formed, the photoresist 232 is removed from the n-type transistors 201A and 201B. The photoresist 232 may be removed by any suitable means known to the skilled artisan. In one or more embodiments, the photoresist 232 may be removed by one or more of ashing or stripping.

With reference to FIGS. 3O and 3P, the etch stop layer 214 on top of the gate 212 is removed. The etch stop layer 214 can be removed by any suitable means known to the skilled artisan. In one or more embodiments, the etch stop layer 214 in the gate contact region is removed by one or more of wet etching and dry etching without the use of a mask. Wet etching may involve the use of hot phosphoric acid. Dry etching may comprise reactive ion etching using gas chemistry including a gas mixture of carbon tetrafluoride (CF₄) and oxygen (O₂).

In one or more embodiments, the contact regions on the source/drain and gate region are filled with a contact metal fill 240. The metal fill 240 may comprise any suitable material. In some embodiments, the contact region is first filled with a barrier metal 242 followed by the metal fill 240. The contact metal 240 and barrier metal 242 may comprise one or more of tungsten (W), molybdenum (Mo), titanium nitride (TiN), tantalum nitride (TaN), cobalt (Co) ruthenium (Ru), and copper (Cu).

FIG. 4A depicts PMOSFET and NMOSFET which have patterned gate and gate dielectrics along with lightly doped drain (LDD) regions. Subsequently, contacts are patterned both P and N MOSFETs, as in FIG. 4B. In order to avoid variation in the height of epitaxial Si, epitaxial Si is grown with over-burden on top of the ILD. Then, the over-burden is planarized using CMP (FIG. 4D). Subsequently, height of epitaxial Si of each type of transistors is adjusted by removing a portion of its epitaxial Si and P+ or N+ doping is performed, selectively while other types of transistors are covered by a mask (FIG. 4F). FIG. 4F steps may be more or less than two steps depending on desired transistor structures. In FIG. 4G, contact for all type of transistors are exposed and filled with barrier metal and conductor. Referring to FIGS. 4A through 4H, in one or more embodiments, a cross-sectional view of a semiconductor device 300 having different types of transistors—low voltage p-transistor 301A and high voltage n-transistor 301B are provided. The low voltage p-type transistor 301A includes a first well region 302 of a first conductivity type, and the high voltage n-transistor 301B includes a second well region 304 of a second conductivity type.

With reference to FIG. 4A, each transistor 301A, 301B may include a well region 302, 304 with an active region defined by isolation regions 306. In one or more embodiments, the shallow trench isolation regions 306 may be defined by a width, W, and a depth, D. In one or more embodiments, the width of the isolation region 306 of the high voltage transistor 301B is in a range of from 0.05 μm to 5 μm and the depth is in a range of from 0.02 μm to 1.0 μm. In one or more embodiments, the width of the isolation region 306 of the low voltage transistors 301A is in a range of from 0.02 μm to 0.5 μm and the depth is in a range of from 0.02 μm to 1.0 μm.

With reference to FIG. 4A, in one or more embodiments, transistor layers are deposited above the isolation regions 306.

The transistor layers deposited on each transistor 301A, 301B may include one or more of a gate oxide layer 310, a gate 212, and a hard mask 316. The gate oxide layer 310 may comprise any suitable material. In one or more embodiments, the gate oxide layer 310 comprises one or more of silicon oxide (SiOx) or silicon oxynitride (SiON). The gate oxide layer 310 may have any suitable thickness. In one or more embodiments, the gate oxide layer 310 has a thickness in a range of from 20 nm to 100 nm.

In one or more embodiments, the gate 312 may comprise any suitable material. In one or more embodiments, the gate 312 comprises one or more of a nitride (N) with silicon (Si), a nitride (N) with tungsten silicon (WSi), or a nitride (N) with silicon tungsten (SiW). The gate 312 may have any suitable thickness. In one or more embodiments, the gate 312 has a thickness in a range of from 20 nm to 100 nm.

In one or more embodiments, the hard mask 316 may comprise any suitable material. In one or more embodiments, the hard mask 316 comprises a moderate temperature oxide. In one or more embodiments, the hard mask 316 may have any suitable thickness. In one or more embodiments, the hard mask 316 has a thickness in a range of from 50 nm to 200 nm.

With reference to FIG. 4A, the transistors 301A, 301B are patterned to form the gate stacks, as described above with respect to transistors 101A and 101B.

In one or more embodiments, a gate spacer 326 is formed on the gate stacks. The gate spacer 326 may comprise any suitable material known to the skilled artisan. In one or more embodiments, the gate spacer 326 comprises silicon oxide (SiOx) or silicon oxynitride (SiOX). The gate spacer 326 may have any suitable thickness. In one or more embodiments, the gate spacer 326 has a thickness in a range of from 20 nm to 200 nm.

In one or more embodiments, an interlayer dielectric layer 328 is then deposited around the gate stacks on the isolation regions 306, and on the doped regions 318, 322. The interlayer dielectric layer 328 may comprise any suitable material known to the skilled artisan. In one or more embodiments, the interlayer dielectric layer 328 comprises silicon oxide (SiOx). The interlayer dielectric layer 328 may have any suitable thickness. In some embodiments, the interlayer dielectric layer 328 has a thickness in a range of from 0.3 μm to 1.0 μm.

Referring to FIG. 4B, the interlayer dielectric layer 328 is patterned to form contact openings 329 over the source/drain region. In one or more embodiments, the number of contact openings 329 in the source/drain regions may be more than one to reduce contact resistance. The interlayer dielectric layer 328 may be patterned using any suitable technique known to the skilled artisan. In one or more embodiments, the interlayer dielectric layer 328 is patterned using reactive ion etching (RIE).

The contact openings 329 may have any suitable critical dimension. In one or more embodiments, the critical dimension of the contact openings 329 is in a range of from 50 nm to 200 nm.

With reference to FIG. 4C, epitaxial silicon 330 (epi-Si) is grown selectively in the contact openings 329 over the source/drain lightly doped regions 318, 322. The epitaxial silicon 330 may have any suitable height, h. In some embodiments, the height, h, of the epitaxial silicon in the source/drain region is in a range of from 500 nm to 1000 nm.

In one or more embodiments, silicon (Si), silicon germanium (SiGe), silicon doped with carbon (Si:C), and combinations thereof, while neither donor nor acceptor, are doped. Silicon sources for epitaxial growth include silicon tetrachloride, dichlorosilane (SiH, Cl), and silane (SiH). In one or more embodiments, the temperature for epitaxial silicon growth is in a range of 400° C. to 1000° C., or from 550° C. to 1000° C.

Referring to FIGS. 4C and 4D, the epitaxial silicon 330 may grow to a height greater than 1000 nm and then may be planarized, e.g., chemical mechanical planarization (CMP), to form a surface substantially co-planar with a top surface of the interlayer dielectric layer 228.

Referring to 4E, the epitaxial silicon 330 of the low voltage transistor 301A is covered with a mask layer 332, and the epitaxial silicon 330 of the high voltage transistor 301B is trimmed and a portion is then doped with an n-type material to form an n-doped epitaxial silicon region 334. The n-type material may be any suitable material known to the skilled artisan. In one or more embodiments, the n-type material used for forming the doped epitaxial silicon 334 comprises one or more of P or As. In one or more embodiments, when phosphorus (P) is used as the dopant, the density of the highly doped epitaxial silicon 334 may be in a range of from 1E17 cm⁻³ to 5E18 cm⁻³ and the implant energy of the highly doped region 236 may be in a range of from 5 keV to 20 keV. In one or more embodiments, when arsenic (As) is used as the dopant, the density of the highly doped region 334 may be in a range of from 1E20 cm⁻³ to 5E20 cm⁻³, and the implant energy of the highly doped region 334 may be in a range of from 5 keV to 20 keV.

Referring to 4F, a photoresist 333 is formed or coated on the interlayer dielectric layer 328 of the high voltage transistor 301B, but not on the low voltage transistor 301A. The photoresist 332 may have any suitable thickness. In one or more embodiments, the photoresist 332 has a thickness in a range of from 0.1μ to 2 μm.

In one or more embodiments, the epitaxial silicon 330 of the low voltage transistor 301A is doped with a P-type material to form a highly doped region 337 of the low voltage transistor 301A. The p-type material may be any suitable material known to the skilled artisan. In one or more embodiments, the p-type material used for forming the doped region 337 comprises one or more of B or BF₂. The density of the highly doped region 337 may be in a range of from 2E17 cm⁻³ to 1E19 cm⁻³.

With reference to FIG. 4G, after the highly doped region 337 is formed, the photoresist 333 is removed from the high voltage transistor 301B. The photoresist 333 may be removed by any suitable means known to the skilled artisan. In one or more embodiments, the photoresist 333 may be removed by one or more of ashing or stripping.

In one or more embodiments, the contact regions on the source are filled with a contact metal fill 340. The metal fill 340 may comprise any suitable material. In some embodiments, the contact region is first filled with a barrier metal 342 followed by the metal fill 340. The contact metal 340 and barrier metal 342 may comprise one or more of tungsten (W), molybdenum (Mo), titanium nitride (TiN), tantalum nitride (TaN), cobalt (Co) ruthenium (Ru), and copper (Cu).

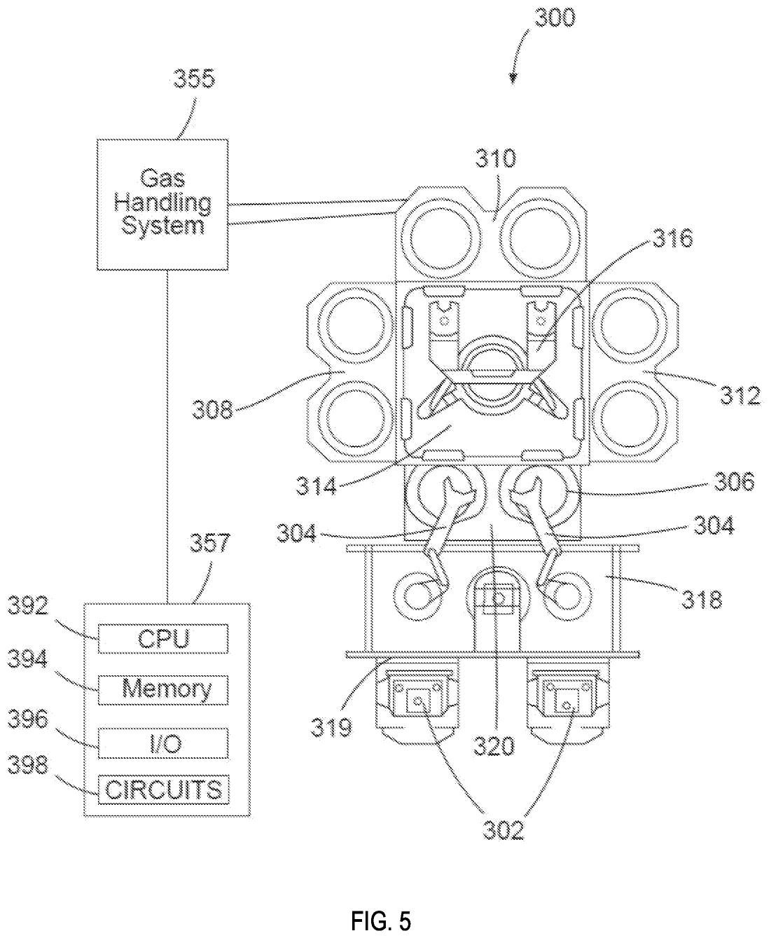

Additional embodiments of the disclosure are directed to processing tools 300 for the formation of the MOSFET devices and methods described, as shown in FIG. 5. A variety of multi-processing platforms known to the skilled artisan may be utilized. The cluster tool 300 includes at least one central transfer station 314 with a plurality of sides. A robot 316 is positioned within the central transfer station 314 and is configured to move a robot blade and a wafer to each of the plurality of sides.

The cluster tool 300 comprises a plurality of processing chambers 308, 310, and 312, also referred to as process stations, connected to the central transfer station. The various processing chambers provide separate processing regions isolated from adjacent process stations. The processing chamber can be any suitable chamber including, but not limited to, a pre-clean chamber, a deposition chamber, an annealing chamber, an etching chamber, a trimming chamber, an epitaxial growth chamber, and the like. The particular arrangement of process chambers and components can be varied depending on the cluster tool and should not be taken as limiting the scope of the disclosure.

In the embodiment shown in FIG. 5, a factory interface 318 is connected to the front of the cluster tool 300. The factory interface 318 includes chambers 302 for loading and unloading on a front 319 of the factory interface 318.

The size and shape of the loading chamber and unloading chamber 302 can vary depending on, for example, the substrates being processed in the cluster tool 300. In the embodiment shown, the loading chamber and unloading chamber 302 are sized to hold a wafer cassette with a plurality of wafers positioned within the cassette.

Robots 304 are within the factory interface 318 and can move between the loading and unloading chambers 302. The robots 304 are capable of transferring a wafer from a cassette in the loading chamber 302 through the factory interface 318 to load lock chamber 320. The robots 304 are also capable of transferring a wafer from the load lock chamber 320 through the factory interface 318 to a cassette in the unloading chamber 302.

The robot 316 of some embodiments is a multi-arm robot capable of independently moving more than one wafer at a time. The robot 316 is configured to move wafers between the chambers around the transfer chamber 314. Individual wafers are carried upon a wafer transport blade that is located at a distal end of the first robotic mechanism.

A system controller 357 is in communication with the robot 316, and a plurality of processing chambers 308, 310 and 312. The system controller 357 can be any suitable component that can control the processing chambers and robots. For example, the system controller 357 can be a computer including a central processing unit (CPU) 392, memory 394, inputs/outputs 396, suitable circuits 398, and storage.

Processes may generally be stored in the memory of the system controller 357 as a software routine that, when executed by the processor, causes the process chamber to perform processes of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general-purpose computer into a specific purpose computer (controller) that controls the chamber operation such that the processes are performed.

In some embodiments, the system controller 357 has a configuration to control the rapid thermal processing chamber to crystallize the template material.

In one or more embodiments, a processing tool comprises: a central transfer station comprising a robot configured to move a wafer; a plurality of process stations, each process station connected to the central transfer station and providing a processing region separated from processing regions of adjacent process stations, the plurality of process stations comprising a recessing chamber, an etching chamber, a deposition chamber; and a controller connected to the central transfer station and the plurality of process stations, the controller configured to activate the robot to move the wafer between process stations, and to control a process occurring in each of the process stations.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods, and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A semiconductor device comprising:
a first transistor comprising a first well region of a first conductivity type, a first gate region disposed above the first well region, and a first contact region including a first epitaxial semiconductor adjacent to the first gate region; and
a second transistor comprising a second well region of a second conductivity, a second gate region disposed above the second well region, and a second contact region including a second epitaxial semiconductor adjacent to the second gate region.

2. The semiconductor device of claim 1, wherein the first epitaxial semiconductor has a height in a range of from 10 nm to 50 nm.

3. The semiconductor device of claim 1, wherein the second epitaxial semiconductor has a height in a range of from 50 nm to 1000 nm.

4. The semiconductor device of claim 1, further comprising:
a first drift region of the second conductivity type and comprising a first lateral portion disposed above a portion of the first well region and adjacent to the first epitaxial semiconductor; and
a second drift region of the first conductivity type and comprising a second lateral portion disposed above a portion of the second well region and adjacent to the second epitaxial semiconductor.

5. The semiconductor device of claim 1, wherein the first gate region comprises a first gate oxide having a thickness in a range of from 1 nm to 10 nm.

6. The semiconductor device of claim 2, wherein the second gate region comprises a second gate oxide having a thickness in a range of from 20 nm to 100 nm.

7. The semiconductor device of claim 1, wherein the first transistor comprises a low voltage MOSFET, and the second transistor comprises a high voltage MOSFET.

8. The semiconductor device of claim 1, further comprising an etch stop layer on a top surface of the first gate region and on a top surface of the second gate region.

9. The semiconductor device of claim 1, wherein the first well region is a P-type region, and the second well region is an N-type region.

10. The semiconductor device of claim 1, wherein the first well region is an N-type region, and the second well region is a P-type region.

11. The semiconductor device of claim 1, wherein the first well region and the second well region are both N-type.

12. The semiconductor device of claim 1, wherein the first well region and the second well region are both P-type.

13. A three-dimensional NAND flash memory integrated circuit, comprising the semiconductor device of claim 1.

14. A method of manufacturing a semiconductor device, the method comprising:
patterning a first contact region on a first transistor and a second contact region on a second transistor;
growing an epitaxial semiconductor on the first transistor and the second transistor; and
trimming a portion of the epitaxial semiconductor on the first transistor.

15. The method of claim 14, wherein the first transistor comprises a first well region of a first conductivity type, a first gate region disposed above the first well region, and the first contact region adjacent to the first gate region.

16. The method of claim 14, wherein the second transistor comprises a second well region of a second conductivity, a second gate region disposed above the second well region, and the second contact region adjacent to the second gate region.

17. The method of claim 15, wherein the first gate region includes a first etch stop on a top surface of the first gate region during growing of the epitaxial semiconductor.

18. The method of claim 16, wherein the second gate region includes a second etch stop layer on a top surface of the second gate region during growing of the epitaxial semiconductor.

19. The method of claim 14, wherein the method is performed without a vacuum break.

20. The method of claim 14, wherein trimming a portion of the epitaxial semiconductor on the first transistor forms a trimmed portion having a height in a range of from 10 nm to 50 nm.
